(19) United States
(12) Patent Application Publication
(10) Pub. No.: US 2012/0193744 A1
(43) Pub. Date: Aug. 2, 2012

(54) IMAGERS WITH BURIED METAL TRENCHES AND THOUGH-SILICON VIAS

(76) Inventors: Swarnal Borthakur, Boise, ID (US); Andrew Perkins, Boise, ID (US); Warren M. Farnworth, Nampa, ID (US); Marc Sulfridge, Boise, ID (US)

(21) Appl. No.: 13/185,366

(22) Filed: Jul. 18, 2011

Related U.S. Application Data
(60) Provisional application No. 61/438,215, filed on Jan. 31, 2011.

(51) Int. Cl. H01L 31/02

(52) U.S. Cl. 257/443; 438/73; 257/E31.113

(57) ABSTRACT

An imaging system may include an imager with frontside components such as imaging pixels and backside components. The backside components may include at least a first redistribution layer having metal trenches and through-silicon vias (TSVs) that couple at least some of the backside components to the frontside components. The metal trenches and through-silicon vias may be formed simultaneously. The through-silicon vias may have a width greater than the width of the metal trenches. The greater width of the through-silicon vias may facilitate forming the through-silicon vias simultaneously with the metal trenches.

This application claims the benefit of provisional patent application No. 61/438,215, filed Jan. 31, 2011, which is hereby incorporated by reference herein in its entirety.

### BACKGROUND

This relates generally to integrated circuits, and more particularly, to imagers with buried metal trenches and through-silicon vias in a backside redistribution layer.

Modern electronic devices such as cellular telephones, cameras, and computers often use digital image sensors. Imagers (i.e., image sensors) may be formed from a two-dimensional array of image sensing pixels. Each pixel receives incident photons (light) and converts the photons into electrical signals.

Modern imagers are sometimes formed with backside circuitry interconnected with one or more backside redistribution layers. Conventional techniques for forming backside redistribution layers and, in particular, conventional techniques for forming a first backside redistribution layer are undesirable in at least some situations.

It would therefore be desirable to provide imagers with improved buried metal trenches and through-silicon vias in a backside redistribution layer and to provide techniques for forming such imagers.

### BRIEF DESCRIPTION OF THE DRAWINGS

FIG. 1 is a diagram of an illustrative integrated circuit with image sensor circuitry that may include buried metal trenches and through-silicon vias in accordance with an embodiment of the present invention.

FIG. 2 is a cross-sectional side view of an illustrative wafer of imagers that be bonded to a carrier in accordance with an embodiment of the present invention.

FIG. 3 is a cross-sectional side view of the illustrative wafer of FIG. 2 showing how the backside of the wafer may be ground down in accordance with an embodiment of the present invention.

FIG. 4 is a cross-sectional side view of the illustrative wafer of FIG. 3 showing how a layer such as a photoresist layer that also serves as a passivation layer may be formed on the backside of the wafer in accordance with an embodiment of the present invention.

FIG. 5 is a cross-sectional side view of the illustrative wafer of FIG. 3 showing how layers such as a temporary photoresist layer and a passivation layer may be deposited on the backside of the wafer in accordance with an embodiment of the present invention.

FIG. 6 is a cross-sectional side view of an illustrative wafer showing how the wafer may be etched to form openings for structures such as through-silicon vias and trenches in accordance with an embodiment of the present invention.

FIG. 7 is a cross-sectional side view of the illustrative wafer of FIG. 6 showing how a layer such as a dielectric passivation layer may be deposited in accordance with an embodiment of the present invention.

FIG. 8 is a cross-sectional side view of an illustrative wafer showing how, if the dielectric passivation layer of FIG. 7 is photo-definable, the bottoms of the through-silicon vias may be opened to reach underlying bond pads in accordance with an embodiment of the present invention.

FIG. 9 is a cross-sectional side view of an illustrative wafer showing how, if the dielectric passivation layer of FIG. 7 is not photo-definable, a layer of photoresist may be deposited and processed such that the bottoms of the through-silicon vias are opened to reach underlying bond pads in accordance with an embodiment of the present invention.

FIG. 10 is a cross-sectional side view of an illustrative wafer showing how openings for structures such as through-silicon vias and trenches may be metalized in accordance with an embodiment of the present invention.

FIG. 11 is a cross-sectional side view of the illustrative wafer of FIG. 10 showing how the backside of the wafer may be planarized in planarization process such as a chemical-mechanical planarization (CMP) process as part of forming a first backside redistribution layer (RDL1) in accordance with an embodiment of the present invention.

FIG. 12 is a cross-sectional side view of the illustrative wafer of FIG. 11 showing how a layer such as an interlevel dielectric passivation layer may be deposited as part of forming a second backside redistribution layer in accordance with an embodiment of the present invention.

FIG. 13 is a cross-sectional side view of the illustrative wafer of FIG. 12 showing how metal lines and vias in a second backside redistribution layer may be formed in accordance with an embodiment of the present invention.

FIG. 14 is a cross-sectional side view of the illustrative wafer of FIG. 13 showing how a layer such as a passivation layer may be deposited on the backside of the wafer in accordance with an embodiment of the present invention.

FIG. 15 is a cross-sectional side view of the illustrative wafer of FIG. 14 showing how a temporary carrier may be removed (if present) and structures such as a solder bump may be formed in accordance with an embodiment of the present invention.

FIG. 16 is a cross-sectional side view of the illustrative wafer of FIG. 15 showing multiple adjacent imagers in accordance with an embodiment of the present invention.

FIG. 17 is a top-sectional side view of the illustrative wafer of FIG. 16 showing how the solder bumps of each imager may be arranged in an array in accordance with an embodiment of the present invention.

FIG. 18 is a top view of an illustrative wafer showing how through-silicon vias and trenches may form a first redistribution layer (RDL1) on the backside of the wafer in accordance with an embodiment of the present invention.

FIG. 19 is a flowchart of illustrative steps involved in forming an imager that may include buried metal trenches and through-silicon vias in accordance with an embodiment of the present invention.

FIG. 20 is a cross-sectional side view of an illustrative wafer showing how openings for structures such as through-silicon vias and trenches may be metalized in accordance with an embodiment of the present invention.

FIG. 21 is a cross-sectional side view of the illustrative wafer of FIG. 20 showing how the backside of the wafer may be planarized in planarization process such as a chemical-mechanical planarization (CMP) process as part of forming a first backside redistribution layer (RDL1) in accordance with an embodiment of the present invention.

FIG. 22 is a cross-sectional side view of the illustrative wafer of FIG. 21 showing how a layer such as an interlevel dielectric passivation layer may be deposited as part of forming a second backside redistribution layer in accordance with an embodiment of the present invention.

FIG. 23 is a cross-sectional side view of the illustrative wafer of FIG. 22 showing how metal lines and vias in a second backside redistribution layer may be formed in accordance with an embodiment of the present invention.

### DETAILED DESCRIPTION

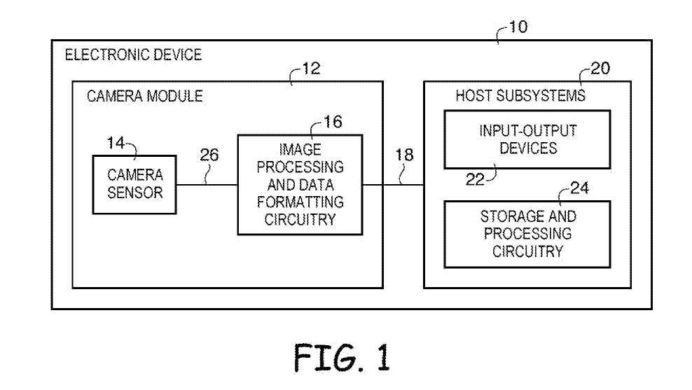

An electronic device with a digital camera module is shown in FIG. 1. Electronic device 10 may be a digital camera, a computer, a cellular telephone, a medical device, or other electronic device. Camera module 12 may include image sensor 14 and one or more lenses. During operation, the lenses focus light onto image sensor 14. Image sensor 14 includes photosensitive elements (i.e., pixels) that convert the light into digital data. Image sensors may have any number of pixels (e.g., hundreds, thousands, millions, or more). A typical image sensor may, for example, have millions of pixels (e.g., megapixels).

Still and video image data from camera sensor 14 may be provided to image processing and data formatting circuitry 16 via path 26. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip or SOC arrangement, camera sensor 14 and image processing and data formatting circuitry 16 are implemented on a common integrated circuit. The use of a single integrated circuit to implement camera sensor 14 and image processing and data formatting circuitry 16 can help to minimize costs.

Camera module 12 (e.g., image processing and data formatting circuitry 16) conveys acquired image data to host subsystem 20 over path 18. Electronic device 10 typically provides a user with numerous high-level functions. In a computer or advanced cellular telephone, for example, a user may be provided with the ability to run user applications. To implement these functions, host subsystem 20 of electronic device 10 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, etc.

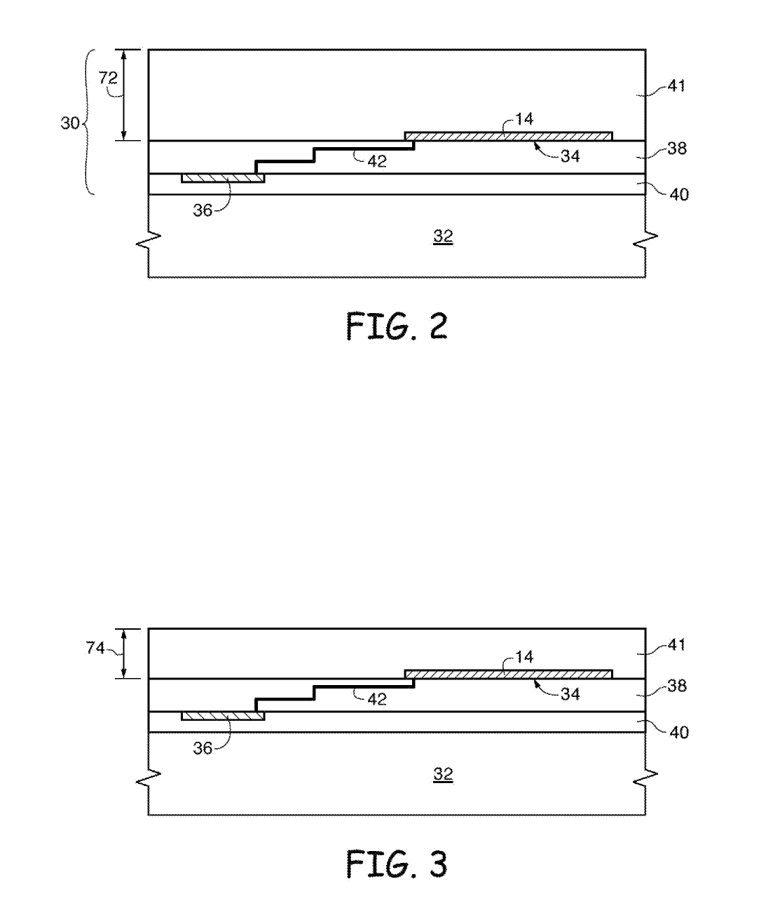

Integrated circuits used to implement camera sensor 14 and, if sensor 14 and circuitry 16 are implemented on integrated chips together in a system on chip arrangement, image processing and data formatting circuitry 16 may be formed on a wafer (e.g., a silicon wafer) in a batch process. The camera sensors 14 on such a wafer may be formed with buried metal trenches and through-silicon vias in a backside redistribution layer. A cross-sectional side view of such a wafer of imager sensors 14 (which also includes, in some embodiments, circuitry 16) is shown in FIG. 2.

As shown in FIG. 2, wafer 30 may be formed from silicon 41 and additional layers such as layers 38 and 40 (as examples, layers 38 and 40 may be nitride and/or oxide layers) and may have a frontside that includes multiple camera sensors 14 (i.e., imagers 14). Each imager 14 may include an image sensor 34 that receives incident light 28 and converts the incident light into electrical signals. Image sensors 34 may be formed, as an example, from arrays of image sensing pixels.

Each imager 14 may also include frontside circuitry such as bond pad 36. Frontside circuitry may, as examples, include transistors, interconnects formed from metal lines and vias such as metal interconnects 42, floating diffusion nodes and other storage devices, and other components associated with imagers such as imagers 14. Frontside circuitry, in each imager 14, may also be connected to external circuits and to backside circuitry (e.g., through one or more through-silicon vias that pass through silicon 41).

As an example, the frontside components of each imager 14 may include one or more contact pads 36 that connect to imaging pixels 34 to backside circuitry associated with that imager 14. In each imager 14, each contact pad 36 may be connected to the circuitry of that imager 14 through one or more conductive lines 42 (e.g., one or more conductive vias and conductive lines) and each contact pad 36 may be connected to backside circuitry associated with that imager 14 through one or more corresponding vias (e.g., one or more through-silicon vias).

As shown in FIG. 2, wafer 30 may be mounted to a carrier (e.g., a temporary carrier such as carrier 32) as part of forming backside circuitry on wafer 30 (e.g., backside circuitry associated with imagers 14). Carrier 32 may be, as examples, a glass carrier, a silicon carrier, or any other desired type of carrier.

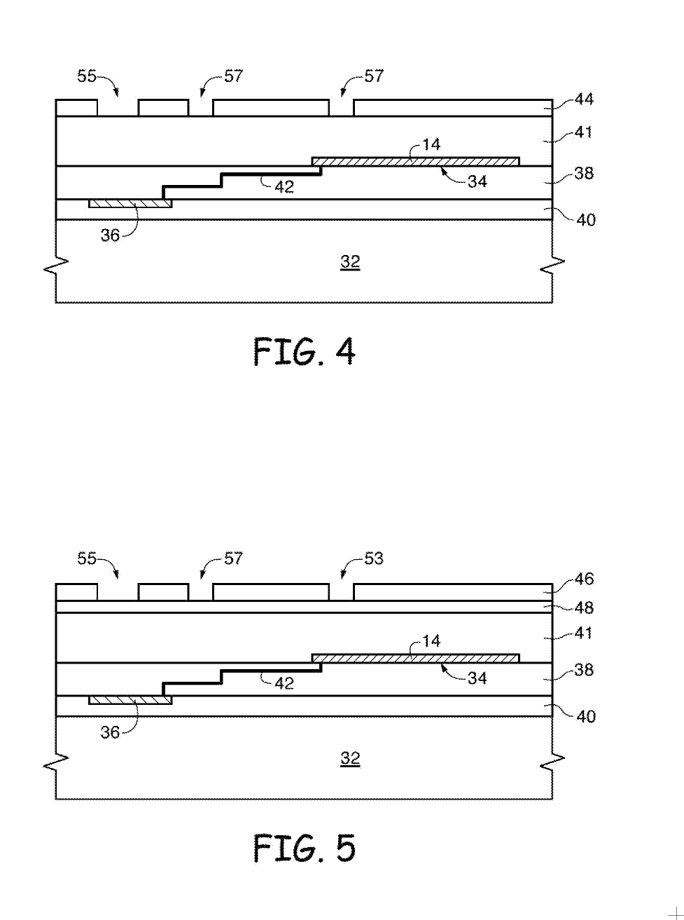

As shown in FIG. 3, wafer 30 may be ground as part of forming backside circuitry on wafer 30. For example, as shown in FIG. 2, silicon 41 may have a thickness 72 prior to being subjected to a grinding process and, as shown in the FIG. 4 example, silicon 41 may have a thickness 74 that is less than thickness 72 following the grinding process. As one example, thickness 74 of silicon 41 may be approximation 100 microns. As examples, grinding silicon 41 down to thickness 74 may involve a coarse grinding process, a fine grinding process, and a chemical-mechanical planarization (CMP) process.

As shown in FIG. 4 and as part of forming backside circuitry on wafer 30 (e.g., as part of forming buried metal trenches and through-silicon vias in a backside redistribution layer), a passivation layer such as passivation layer 44 may be deposited on silicon 41 of wafer 30. Depositing passivation layer 44 may involve a spinning process in which wafer 30 is spun and passivation layer 44, in a liquid form, is spread across wafer 30. With one suitable arrangement, passivation layer 44 may be a photodeterminable film (e.g., a permanent photoresist layer that may also act as a passivation layer).

In arrangements utilizing temporary photoresist layers, forming backside components on wafer 30 may include depositing a passivation layer 48 (e.g., a permanent passivation layer) and depositing a temporary photoresist layer 46, as shown in FIG. 5.

After layer 44 of FIG. 4 (or layer 46 of FIG. 5) is formed, layer 44 (or layer 46) may be photolithographically exposed and developed. After being developed, layer 44 (or layer 46) may include openings 55 and 57, which may later be formed into interconnects such as through-silicon vias and buried metal trenches.

After layer 44 (or layer 46) is developed, layer (or layer 46) may be etched. With one suitable arrangement, layer 44 (or layer 46) may be etched using the well-known Bosch process, which produces nearly vertical etched structures. If temporary photoresist layer 46 is used, any remaining photoresist may be removed after photolithographically exposing and etching layer 46.

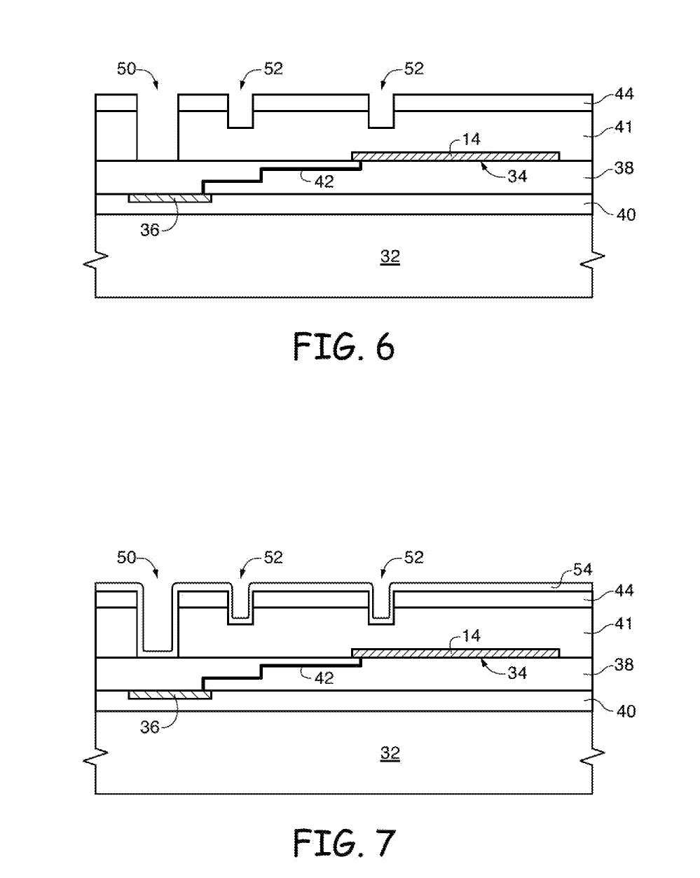

After photolithographically exposing and etching layer 44 (or layer 46), wafer 30 may include holes for through-silicon vias 51 such as holes 50 and holes for buried metal trenches 53 such as holes 52, as shown in FIG. 6.

The speed of the etching process applied to silicon 41 to form holes for through-silicon vias 51 and holes for buried metal trenches 53 may be dependent on the size of the photolithographic features (e.g., the size of features removed from photodeterminable passivation film 44 or photoresist layer 46 during the photolithographic exposure processes). As an example, larger (e.g., wider) structures may be more deeply etched than smaller (e.g., narrower) structures, when both types of structures are subjected to the same etching processes. As a result of these properties of the etching process applied to silicon 41, the holes for through-silicon vias 51 may have greater depths than the depths of the holes for buried metal trenches 53, even though the holes for vias 51 and trenches 53 were subjected to the same etching processes. With one suitable arrangement, these properties of the etching process applied to silicon 41 (e.g., the relation that etching depth increases with the size or width of an etched opening) may be achieved using a dry etching process.

By etching holes for through-silicon vias 51 deeper than the holes for metal trenches 53 in a single etching process (using the relation that etching depth, or etching speed, may increase with the size or width of an etched opening), it may be possible to form the holes for both vias 51 and trenches 53 essentially simultaneously. Because of the greater width of the holes 55 (and 50) for the through-silicon vias 51, the holes for vias 51 may be etched deeply enough to extend through silicon 41 all the way to oxide 38. In addition, because of the narrower width of the holes 57 (and 52) the metal trenches 53, the holes for trenches 53 may not extend as deep as the vias 51 and may therefore be shallow enough to avoid interfering with frontside components such as image sensors 34 and frontside circuitry.

In general, any desired process may be utilized in forming the holes 50 and 52 for through-silicon vias 51 and trenches 53. As examples, laser ablation methods, Bosch processes, and other photolithographic processes may be utilized in forming the holes for vias 51 and trenches 53.

After the holes for vias 51 and trenches 53 have been formed (e.g., after processing of wafer 30 has reached the stage shown in FIG. 6), a layer such as a dielectric passivation layer 54 may be deposited as shown in FIG. 7.

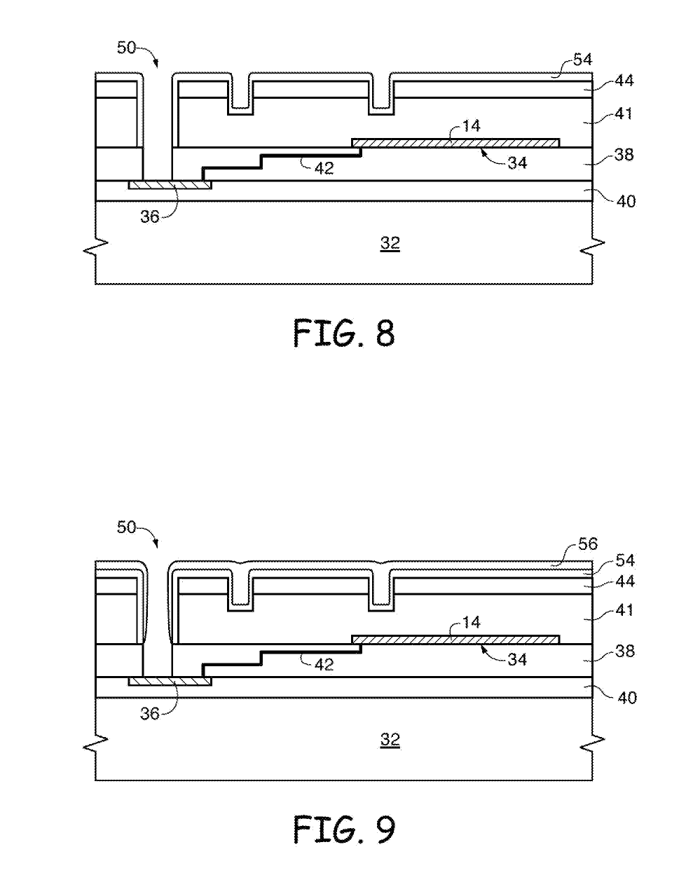

If dielectric passivation layer 54 is photo-definable, the bottoms of openings 50 may be opened through to bond pads 36 (e.g., by photolithographically exposing and developing the layer 54 at the via bottom and dry etching the oxide layer 38) as shown in FIG. 8.

With other suitable arrangements (e.g., if dielectric passivation layer 54 is not photo-definable), photoresist layer 56 may be deposited, exposed, and developed and photoresist layer 56 as well as the oxide layer 38 may be dry etched as shown in FIG. 9 to open the bottoms of openings 50 through to bond pads 36. Any remaining photoresist may be removed after opening the bottoms of openings 50 through to bonds pads 36.

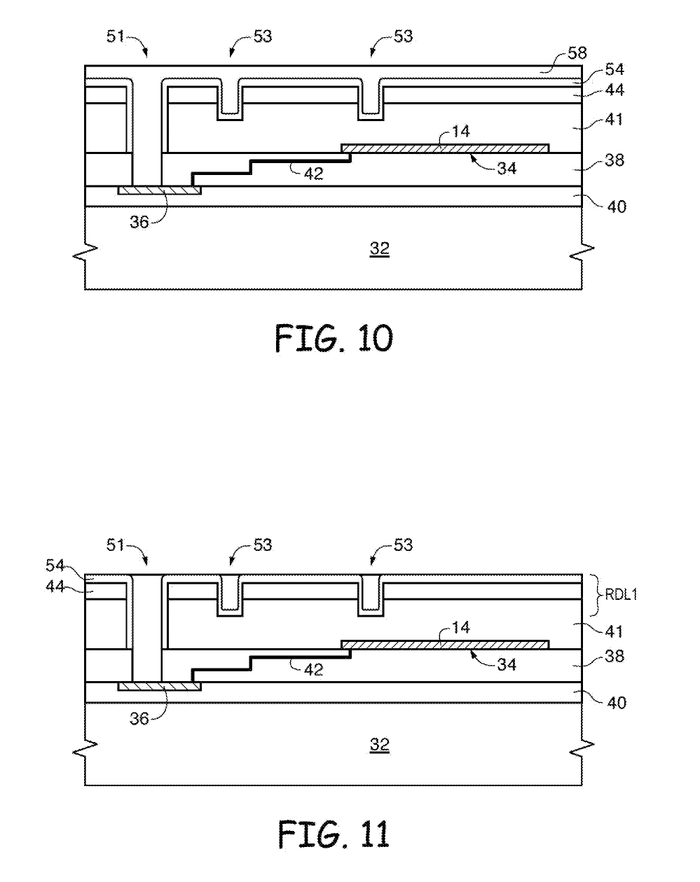

After the holes for vias and trenches have been formed, the holes may be metalized. As shown in the example of FIG. 10, metal 58 may be deposited within the holes for vias 51 and trenches 53 and above layer 48 to form vias 51 and trenches 53. With one suitable arrangement, metal 58 may be conductive and may be electrically coupled to contact pad 36 (e.g., metal 58 may be deposited onto contact pad 36).

Through-silicon vias 51 and trenches 53 may be formed (as shown in FIG. 10) using any desired processes. As an example, forming vias 51 and trenches 53 may involve depositing an initial layer (e.g., a barrier layer, an adhesion layer, or a combination of these and other layers), depositing a seed layer, and depositing metal (e.g., plating metal onto the seed layer or the initial layer, flowing metal onto the seed layer or the initial layer, etc.).

After forming vias 51 and trenches 53 (as shown in FIG. 10), wafer 30 may be planarized as shown in FIG. 8. As an example, a chemical-mechanical planarization (CMP) process may be applied to wafer 30. The CMP process may, as an example, remove excess metal 58 (e.g., metal extending above layer 48) deposited when forming vias 51 and trenches 53.

Vias 51 and trenches 53 may form a first backside redistribution layer RDL1. The first backside redistribution layer RDL1 may serve to interconnect backside circuitry and additional backside redistribution layers with frontside circuitry such as sensors 34 through contact pads 36.

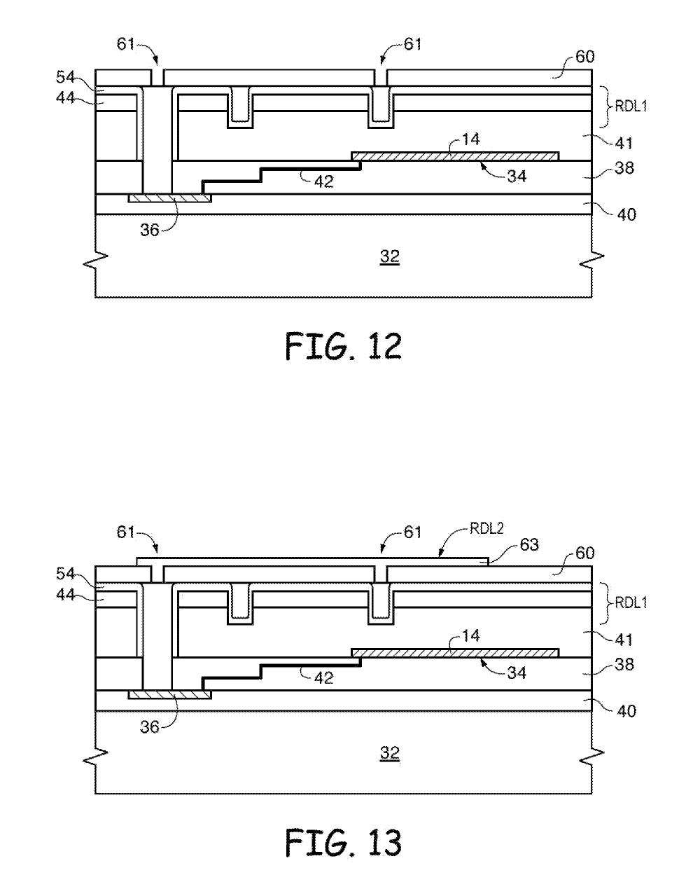

After forming the first backside redistribution layer RDL1, one or more additional backside redistribution layers RLD2+ may (optionally) be formed. As shown in FIG. 12, a layer such as interlevel dielectric passivation layer 60 may be deposited on layer 48 (and vias 51 and trenches 53). Openings 61 may be formed in layer 60 for vias (and metal lines) in a second backside redistribution layer (RDL2). As shown in FIG. 13, metal 63 may be deposited to formed traces (and vias) in the second backside redistribution layer (RDL2).

In the example of FIG. 10, metal 58 is illustrated as coating the holes for vias 51 and entirely filling the holes for vias 51. This is merely an example of some arrangements. With other suitable arrangements, metal 58 may completely not fill the holes for vias 51 or the upper surface of metal 58 may sometimes exhibit depressions above vias 51. It may be possible to adjust whether or not metal 58 fills the holes for the vias 51 by adjusting the amount of metal 58 deposited. For example, by increasing the amount of metal 58 deposited (e.g., by increased the plating time), it may be possible to ensure metal 58 fills the holes for the vias 51. In arrangements in which metal 58 does not completely fill the voids for vias 51 (or trenches 53), dielectric material or other material may be deposited to fill the remaining voids.

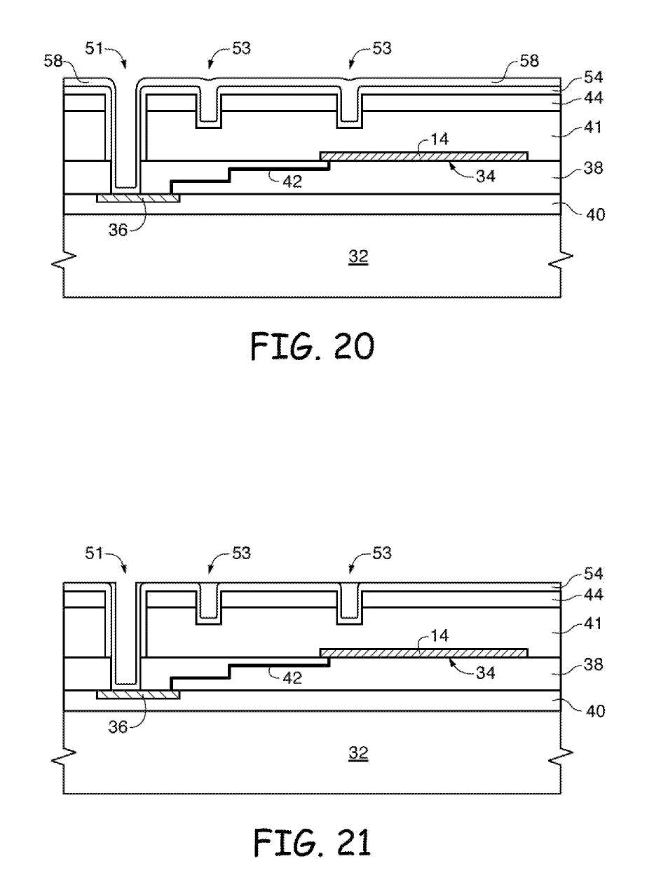

Arrangements in which metal 58 does not completely fill the holes for vias 51 are shown in FIGS. 20, 21, 22, and 23.

As shown in the example of FIG. 20 (and after holes 50 and 52 for vias and trenches have been formed, the holes may be metalized), metal 58 may be deposited within holes 50 and 52 to form vias 51 and trenches 53. With one suitable arrangement, metal 58 may be conductive and may be electrically coupled to contact pad 36 (e.g., metal 58 may be deposited onto contact pad 36).

In the example of FIG. 20, metal 58 is illustrated as coating the sidewalls of holes 52 for vias 51. This is merely an example of some arrangements.

After forming vias 51 and trenches 53 (as shown in FIG. 20), wafer 30 may be planarized as shown in FIG. 21. As an example, a chemical-mechanical planarization (CMP) process may be applied to wafer 30. The CMP process may, as an example, remove excess metal 58 (e.g., metal extending above layer 54) deposited when forming vias 51 and trenches 53.

Vias 51 and trenches 53 may form a first backside redistribution layer RDL1. The first backside redistribution layer RDL1 may serve to interconnect backside circuitry and additional backside redistribution layers with frontside circuitry such as sensors 34 through contact pads 36.

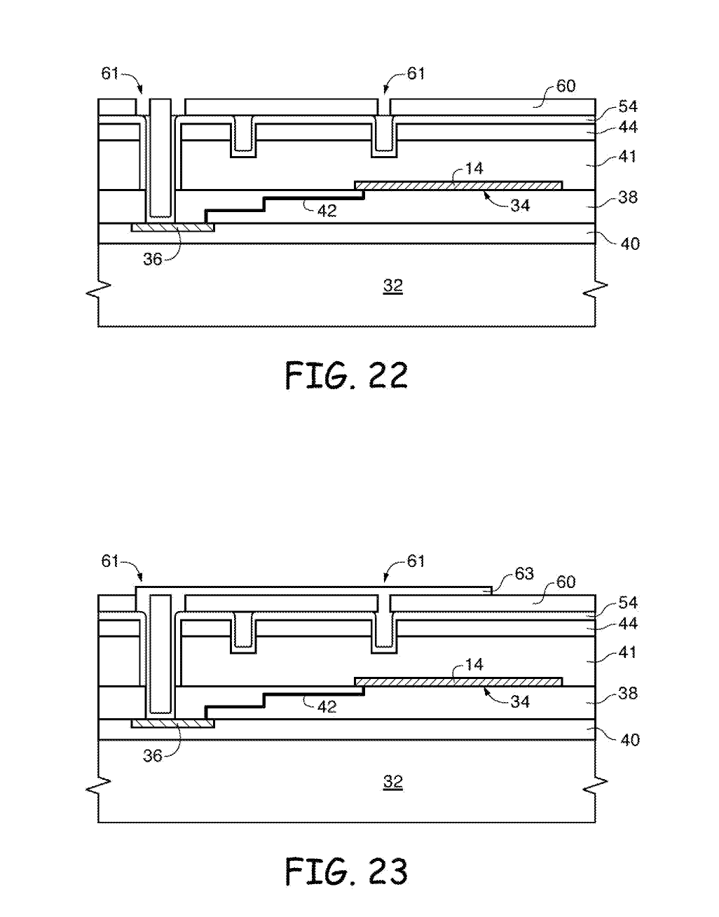

After forming the first backside redistribution layer RDL1, one or more additional backside redistribution layers RLD2+ may (optionally) be formed. As shown in FIG. 22, a layer such as interlevel dielectric passivation layer 60 may be deposited on layer 54. Interlevel dielectric passivation layer 60 may also fill in holes 52 for vias 51 (as shown in FIG. 22). Openings 61 may be formed in layer 60 for vias (and metal lines) in a second backside redistribution layer (RDL2). As shown in FIG. 23, metal 63 may be deposited to formed traces (and vias) in the second backside redistribution layer (RDL2).

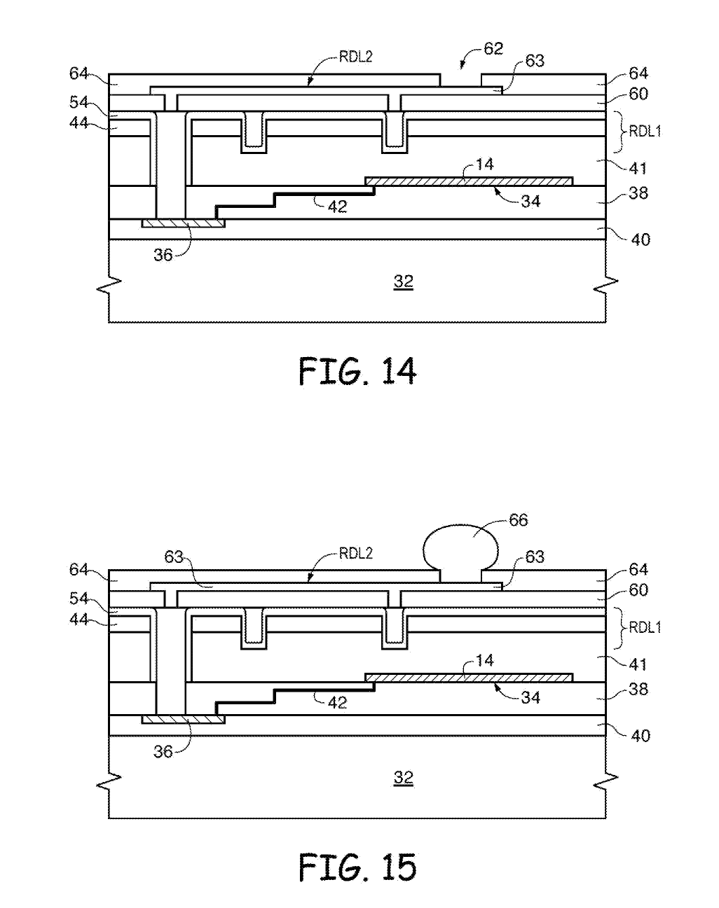

As shown in FIG. 14, a passivation layer such as layer 64 may be formed and openings such as opening 62 may be formed in layer 64. As shown in FIG. 15, carrier 32 may be separated from wafer 30 and solder bumps such as solder bump 66 may be formed. If carrier 32 is a permanent carrier (e.g., a carrier formed from glass), there may be no need to separate carrier 32 from wafer 30.

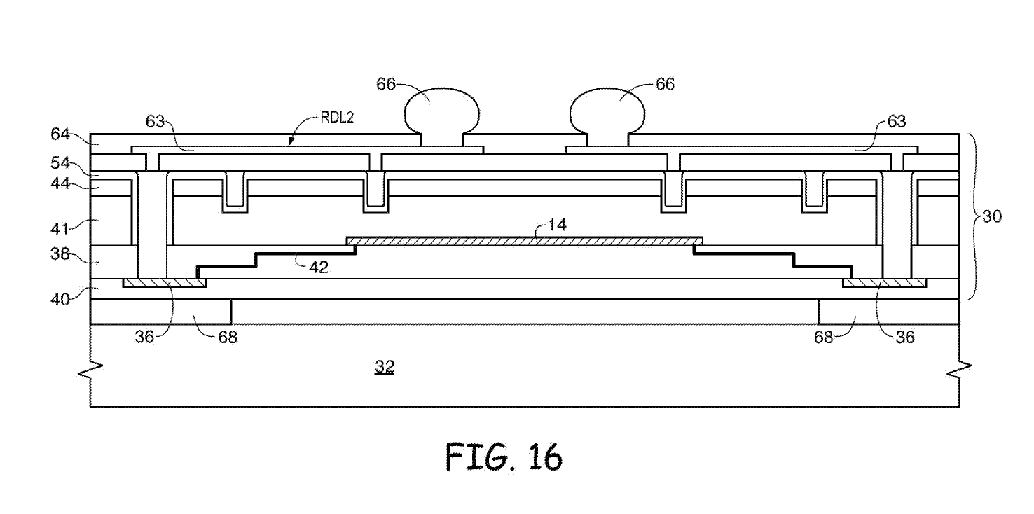

A cross-sectional side view of multiple adjacent imagers 34 is shown in FIG. 16. As shown in FIG. 16, adhesive such as adhesive 68 may be used to hold carrier 32 in place. If carrier 32 is a permanent carrier (e.g., a transparent carrier), adhesive may be arranged between imagers 34 as shown in FIG. 16. With other suitable arrangements (e.g., when carrier 32 is a temporary carrier removed as shown in FIG. 15), adhesive may, if desired, be disposed along more of (or the entirety of) the interface between carrier 32 and wafer 30 (e.g., layer 40). This type of arrangement may reduce stresses on wafer 30 during processing (relative to the arrangement of adhesive 68 shown in FIG. 16). If desired, adhesive 68 (whether or not extending along more of the interface between carrier 32 and wafer 30) may be formed from ethylene-vinyl-acetate (EVA), which is a clear and UV stable adhesive.

If desired, photo-definable and permanent dry film resists may be used for materials in any desired layers such as layers 44, 46, 48, and 56.

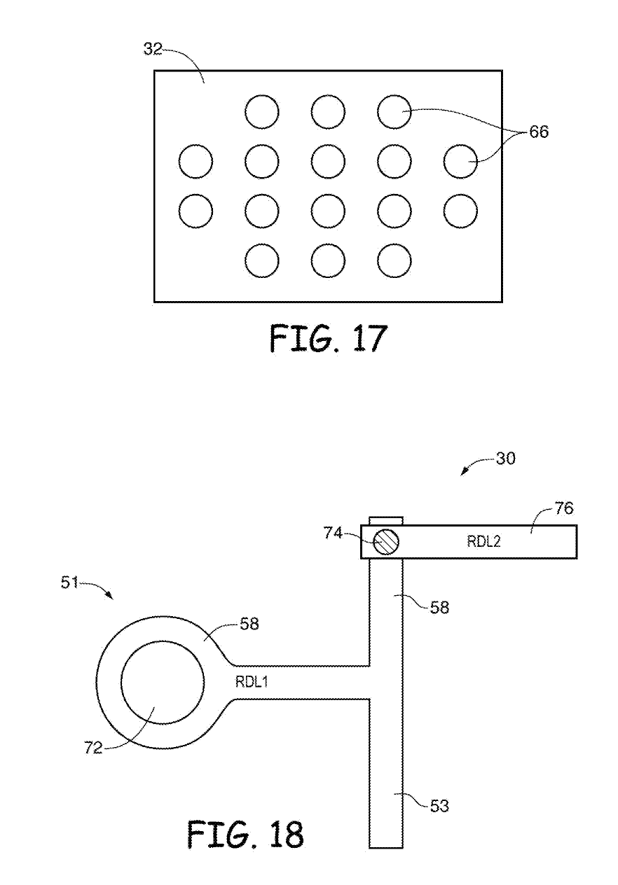

As shown in the top-view of FIG. 17, solder bumps 66 may be arranged in a ball grid array pattern. With one suitable arrangement, backside circuitry (e.g., circuitry coupled to solder bumps 66) may be formed as a broadcast antenna as well as interconnects (e.g., x-y-z plane conductive trace patterns). If a battery or other power source such as a solar cell and capacitor were also included, device 10 may form a fully self contained broadcast camera system.

As examples, backside circuitry may include external bond pads, communications circuitry, input-output circuitry, image processing circuitry, image capture circuitry (e.g., bias generator circuitry, sample-and-hold circuitry, address circuitry, etc.), as well as other desired circuits and components. Backside circuitry maybe connected to frontside circuitry such as sensors 34 through RDL1 (and optional redistribution layers RDL2+).

In the some arrangements, metal 58 for vias 51 does not entirely fill in the holes for vias 51. In arrangements of this type, dielectric 60 may be deposited in what remains of holes 50 for vias 51. Dielectric 60 may be a dry film dielectric, as an example. In other arrangements in which metal 58 for vias 51 entirely fills in the holes for vias 51, the dielectric deposited for the second redistribution layer may not be a dry film dielectric (e.g., standard dual-damascene processes may be used in forming redistribution layers RDL2+ when metal 58 for vias 51 entirely fills in the holes for vias 51). Standard dual-damascene processes may be used in forming any redistribution layers above the second redistribution layer.

A top view of wafer 30 is shown in FIG. 18. As shown in FIG. 10, vias 51 may have a circular shape with a ring of metal 58 surrounding dielectric 72 (e.g., dielectric 60). The circular shape shown in FIG. 18 is merely illustrative. In general, vias 51 may be any suitable shape such as circular, triangular, rectangular, polygonal, etc.

The top view of FIG. 18 illustrates how redistribution layers RDL1 and RDL2 may convey signals from vias 51 to other areas of the backside of wafer 30. As shown in FIG. 18, RDL2 may include vias 74 and metal lines 76 (e.g., trenches 76).

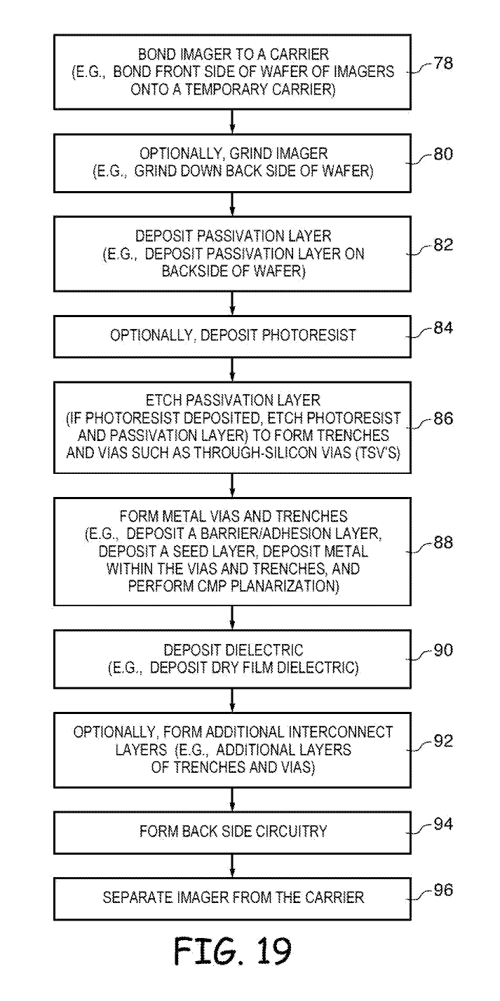

A flowchart of illustrative steps involved in forming an imager that may include buried metal trenches and through-silicon vias (TSVs), is shown in FIG. 19.

In step 78, an imager such as imager 14 may be bonded to a carrier. As an example, imagers 14 on wafer 30 may be bonded to a temporary carrier. As shown in FIG. 2 in connection with step 78, the frontside of wafer 30 may be bonded to carrier 32.

In optional step 80, one or more grinding processes may be applied to imager 14. As an example, one or more grinding processes (e.g., a coarse grinding process, a fine grinding process, and a CMP process) may be performed on the backside of wafer 30, as shown in FIG. 3.

In step 82, a passivation layer such as passivation layer 44 of FIG. 4 may be deposited on imager 14 (e.g., layer 44 may be deposited on the backside of wafer 30). The passivation layer may, if desired, be a photo-definable passivation layer (e.g., a passivation layer with properties similar to that of photoresist materials and that can be photolithographically processed).

In optional step 84, a layer of photoresist may be deposited on imager 14. Photoresist may be deposited on the backside of wafer 30. In some arrangements, photoresist such as photoresist 46 of FIG. 5 may be deposited on the backside of wafer 30 when the passivation material such as passivation material 48 of FIG. 5 deposited in step 82 is not photo-definable.

In step 86, passivation layer 44 (together with the optional layer of photoresist that may have been deposited in step 84, if the photoresist was deposited) may be etched to form openings for trenches and vias such as trenches 53 and vias 51, as shown in connection with FIG. 6. As one example, step 86 may include a photolithographic exposure process, a process to remove exposed (or unexposed, if a negative photo-definable passivation layer or photoresist material is used) portions of the passivation layer (or photoresist material, if the photoresist material is deposited in optional step 84), and an etching process.

In step 88, metal lines 53 and through-silicon vias 51 may be formed. As one example, forming lines 53 and TSVs 51 may involve depositing a barrier layer (e.g., depositing a passivation layer on the bottom and sidewalls of openings 50 for TSVs 51 and openings 52 for metal lines 53), an adhesion layer, a seed layer, and a metal layer, or any desired combination of these and other layers, as shown in FIG. 10. Step 88 may, if desired, also include a CMP process, as shown in FIG. 11.

In step 90, dielectric material such as material 72 may be deposited. As an example, material 72 may be deposited on the backside of wafer 30. In some arrangements, the deposited dielectric material may be a dry film dielectric. As one example, dry film dielectric may be deposited in step 90 when the metal deposited in the openings for TSVs 51 does not completely fill-in the openings, as illustrated in the example of FIG. 18. In arrangements in which the metal deposited in the openings for TSVs 51 completely fills the openings for TSVs 51, dry film dielectric or other dielectric materials such as layer 60 of FIG. 12 may be deposited in step 90. If desired, dielectric materials other than dry film dielectrics may be deposited in step 90, even in arrangements in which the metal deposited in the openings for TSVs 51 does not completely fill-in the openings for TSVs 51.

In optional step 92, additional interconnect layers be formed on the backside of imager 14 (e.g., on the backside of wafer 30). The optional additional interconnect layers may include vias and trenches and may be formed using any suitable processing techniques.

In step 94, optional back side circuitry 8 may be formed. Back side circuitry may include, as examples, external bond pads, communications circuitry, input-output circuitry, image processing circuitry, image capture circuitry (e.g., bias generator circuitry, sample-and-hold circuitry, address circuitry, etc.), as well as other desired circuits and components.

In step 96, imagers 14 may be separated (i.e., singulated) from the temporary carrier attached in step 78. As one example, wafer 30 may be detached from carrier 32.

While FIGS. 2-17 show many frontside components of wafer 30 already formed (e.g., image sensors 34, frontside circuitry, and contact pad 36 are already formed in the FIG. 2 example), the frontside components of wafer 30 may, in general, be formed at any desired time. As an example, the frontside components of wafer 30 may be formed after the formation of backside components (e.g., after the processes shown and described in connection with FIGS. 2-177).

Various embodiments have been described illustrating imagers with buried metal trenches and through-silicon vias in a backside redistribution layer.

An imaging system may include an imager with frontside components such as imaging pixels and backside components. The backside components may include at least a first redistribution layer having metal trenches and through-silicon vias (TSVs) that couple at least some of the backside components to the frontside components.

The metal trenches and through-silicon vias may form a first backside redistribution layer. Backside redistribution layers may interconnect backside components and circuitry. The through-silicon vias of the first backside redistribution layer may couple frontside components such as frontside transistors and the image pixels to the backside components.

The metal trenches and through-silicon vias may be formed approximately simultaneously using processing steps common to both the metal trenches and through-silicon vias. With some suitable arrangements, the through-silicon vias may be formed with larger openings than the metal trenches. This may facilitate use of one or more processing steps that simultaneously form holes for the through-silicon vias and for the metal trenches. As an example, holes for the through-silicon vias may be etched to a first depth (e.g., a depth sufficient to connect to frontside components) while holes for the metal trenches are simultaneously etched to a second and lesser depth (e.g., a depth small enough to ensure that the metal trenches do not interfere with the operation of front side components such as the imaging pixels).

The foregoing is merely illustrative of the principles of this invention which can be practiced in other embodiments.

What is claimed is:

1. A method of forming an imager in a substrate having a first side, a second side, and a thickness, wherein the imager comprises at least one light sensing element located on the first side of the substrate, the method comprising:
simultaneously etching at least first and second openings in the second side of the substrate; and
forming a through via from the first opening and forming a metal trench from the second opening by depositing conductive material in the first and second openings, wherein the through via is coupled to the conductive trench, passes through at least some of the thickness of the substrate, and is coupled to at least one circuit on the first side of the imager.

2. The method defined in claim 1 wherein simultaneously etching the first and second openings in the second side of the substrate comprises:
etching the first opening to a first depth in the second side of the substrate; and
etching the second opening to a second depth in the second side of the substrate, wherein the first depth is greater than the second depth.

3. The method defined in claim 2 wherein the first opening has a first width, wherein the second opening has a second width, wherein the first and second widths are measured in a direction perpendicular to the thickness of the substrate, and wherein simultaneously etching the first and second openings in the second side of the substrate comprising etching the first and second openings such that the first width is greater than the second width.

4. The method defined in claim 1 wherein the first opening has a first width, wherein the second opening has a second width, wherein the first and second widths are measured in a direction perpendicular to the thickness of the substrate, and wherein simultaneously etching the first and second openings in the second side of the substrate comprising etching the first and second openings such that the first width is greater than the second width.

5. The method defined in claim 1 wherein forming the through via comprises depositing an amount of conductive material sufficient to coat walls of the first opening.

6. The method defined in claim 1 wherein forming the through via comprises depositing an amount of conductive material sufficient to coat walls of the first opening but insufficient to completely fill the first opening.

7. The method defined in claim 6 further comprising depositing a dry film dielectric in the first opening such that the first opening is completely filled by the conductive material and the dry film dielectric.

8. The method defined in claim 6 further comprising depositing dielectric in the first opening such that the first opening is completely filled by the conductive material and the dielectric.

9. The method defined in claim 1 wherein forming the through via comprises depositing an amount of conductive material sufficient to completely fill the first opening.

10. The method defined in claim 1 wherein etching the first opening comprises etching a circular opening in the second side of the substrate and wherein forming the through via comprising forming a circular through via in the circular opening.

11. The method defined in claim 1 wherein etching the first opening comprises etching a rectangular opening in the second side of the substrate and wherein forming the through via comprising forming a rectangular through via in the rectangular opening.

12. A method of forming a plurality of imagers in a wafer having a first side and a second side, wherein the wafer comprises a plurality of image sensors located on the first side of the wafer, the method comprising:
simultaneously etching at least first and second pluralities of openings in the second side of the wafer, wherein simultaneously etching the first and second pluralities of openings in the second side of the wafer comprises:
etching the first plurality of openings to a first depth in the second side of the wafer; and
etching the second plurality of openings to a second depth in the second side of the wafer, wherein the first depth is greater than the second depth; and
forming a plurality of through vias from the first plurality of openings and forming a plurality of metal trenches from the second plurality of openings by depositing conductive material in the first and second pluralities of openings.

13. The method defined in claim 12 further comprising:
prior to simultaneously etching the first and second pluralities of openings in the second side of the wafer, bonding the first side of the wafer to a temporary carrier.

14. The method defined in claim 12 further comprising:
prior to simultaneously etching the first and second pluralities of openings in the second side of the wafer, planarizing the second side of the wafer.

15. The method defined in claim 12 further comprising:
prior to simultaneously etching the first and second pluralities of openings in the second side of the wafer, depositing a photo-definable passivation layer.

16. The method defined in claim 12 wherein depositing the conductive material in the first and second pluralities of openings comprises depositing the conductive material onto the second side of the wafer such that some of the conductive material is deposited in the first and second pluralities of openings and some of the conductive material is deposited on an exterior surface of the wafer, the method further comprising:
removing the conductive material that was deposited on the exterior surface of the wafer using at least one planarization process.

17. An imager comprising:
a substrate having a first side and a second side;
a plurality of image sensing pixels located on the first side of the substrate;
at least a first redistribution layer located on the second side of the substrate, wherein the first redistribution layer includes a conductive trench and a through via, wherein the through via is coupled to the conductive trench, passes through at least a portion of the substrate, and is coupled to the image sensing pixels on the first side of the substrate, and wherein the through via comprises conductive material that at least partially surrounds dielectric material.

18. The imager defined in claim 17 wherein the through via has a circular shape and wherein the conductive material of the through via is a ring that at least partially surrounds the dielectric material.

19. The imager defined in claim 17 wherein the through via has a rectangular shape.

20. The imager defined in claim 17 wherein the dielectric material comprises a dry film dielectric.
